(19) United States
(12) Patent Application Publication
(10) Pub. No.: US 2025/0219331 A1
(43) Pub. Date: Jul. 3, 2025

(54) CABLE TAP HAVING A BIASING PORTION STRUCTURALLY CONFIGURED TO MAINTAIN ELECTRICAL CONTACT BETWEEN A FIRST HOUSING PORTION AND A SECOND HOUSING PORTION TO PROVIDE GROUNDING AND ENHANCED RF SHIELDING

(71) Applicant: PPC BROADBAND, INC., East Syracuse, NY (US)

(72) Inventor: Roger MATHEWS, Syracuse, NY (US)

(73) Assignee: PPC BROADBAND, INC., East Syracuse, NY (US)

(21) Appl. No.: 19/004,689

(22) Filed: Dec. 30, 2024

Related U.S. Application Data
(60) Provisional application No. 63/615,662, filed on Dec. 28, 2023.

(51) Int. Cl. H01R 13/659; H05K 9/00

(52) U.S. Cl. CPC H01R 13/659; H05K 9/0081

(57) ABSTRACT

A cable tap structurally configured to maintain an electrical ground between loosely coupled housing portions to prevent or inhibit radio frequency interference. The cable tap may include a first housing portion structurally configured to connect to an input communication cable, a second housing portion structurally configured to connect an output communication cable, a signal processing portion structurally configured to receive and process a signal from the input communication cable and route a processed signal to the output communication cable; and a biasing portion structurally configured to maintain an electrically conductive connection between the first housing portion and the second housing portion when the first housing portion is loosely coupled with the second housing portion and the signal processing portion is receiving the signal from the input communication cable so as to ground the first housing portion to the second housing portion and provide enhanced RF shielding.

### CROSS-REFERENCE TO RELATED APPLICATION

This application claims the benefit of U.S. Provisional Patent Application No. 63/615,662, filed on Dec. 28, 2023, the disclosure of which is hereby incorporated by reference herein in its entirety.

### TECHNICAL FIELD

The present disclosure relates generally to cable taps for distributing radio frequency (RF) signals in a communication network, and more particularly to cable tap having a biasing portion structurally configured to maintain electrical contact between a first housing portion and a second housing portion to provide grounding and to minimize RF leakage.

### BACKGROUND

Cable taps are used to distribute radiofrequency (RF) signals in a coaxial cable television network. A CATV network consists of interconnected coaxial cables and components such as repeating amplifiers, signal splitters, signal combiners, cable taps and other signal conveying devices to achieve two-way communication of signals between a network provider based at a “head-end” to a subscriber.

A cable tap is a passive electronic device used to distribute television signals. The cable tap is used to “tap off” a part of the available signal from the provider and send it to a TV or multiple TV's. A cable tap can include an input port, an output port (or ports), and a plurality of tap ports. Typically, the input port and the output are arranged on a back box and the plurality of tap ports are arranged on a face plate along with the circuitry to manipulate the RF signals for distribution to the home or residence in the network. The face plate is removably attached to a back box so that it can be separated from the back box for upgrades, repairs, and general duties of maintaining the network. For example, the face plate may be attached to the back box by fasteners.

Cable taps also typically include an environmental seal and RF gasketing between the mating structure of the back box and the face plate. For the environmental seal and the RF gasketing to work effectively, the back box and the face plate must be properly secured together. If the face plate and back box break contact along the mating structures (e.g., due to corrosion or if the fasteners are not tightened fully), the RF gasket and the environmental seal may lose contact with the corresponding mating structure of the plate or main housing portion. As a result, RF energy may escape outside to the atmosphere creating interference with wireless communications.

Therefore, it may be desirable to provide a cable tap that is configured to reduce RF interference if the RF gasket and the environmental seal lose contact with the corresponding mating structure of the plate or main housing portion. For example, it may be desirable to provide a cable tap having a biasing portion structurally configured to maintain electrical contact between a first housing portion and a second housing portion so as to ground the first housing portion with the second housing portion when the cable tap is in a loose condition to prevent or inhibit radio frequency interference.

### SUMMARY

According to various embodiments of the present disclosure, a cable tap is provided that may be structurally configured to maintain an electrical ground between loosely coupled housing portions to prevent or inhibit radio frequency interference.

In some embodiments, the cable tap may include a first housing portion structurally configured to connect to an input communication cable and a second housing portion structurally configured to be coupled with the first housing portion and to connect to an output communication cable. In some embodiments, the first housing portion may include a first mounting portion and the second housing portion may include a second mounting portion structurally configured to contact the first mounting portion when the second housing portion is attached to the first housing portion.

In some embodiments, the cable tap may include a biasing portion structurally configured to create an electrically conductive connection between the first housing portion and the second housing portion.

In some embodiments, the cable tap may include a radio frequency shielding portion supported on the first mounting portion and structurally configured to engage the second mounting portion to form a radio frequency barrier therebetween.

In some embodiments, the cable tap may include a sealing portion supported on the first mounting portion and structurally configured to engage the second mounting portion to form a water-resistant seal therebetween.

In some embodiments, the second housing portion may include a signal processing portion structurally configured to receive and process a signal from the input communication cable and route a processed signal to the output communication cable.

In some embodiments, the first housing portion and the second housing portion may be structurally configured to enclose the signal processing portion when the second housing portion is attached to the first housing portion.

In some embodiments, the radio frequency shielding portion may be positioned inward of the sealing portion.

In some embodiments, the biasing portion may be positioned outward of the radio frequency shielding portion and the sealing portion.

In some embodiments, the biasing portion may be structurally configured to maintain the electrically conductive connection between the first housing portion and the second housing portion when the first housing portion is loosely coupled with the second housing portion and first mounting portion and the second mounting portion are not in contact and the signal processing portion is receiving the signal from the input communication cable so as to ground the first housing portion to the second housing portion and provide enhanced RF shielding.

In some embodiments, the biasing portion may include a coil spring.

In some embodiments, the first housing portion may include a first attachment portion and the second housing portion may include a second attachment portion. In some embodiments, the first attachment portion and the second attachment portion may be structurally configured to engage a fastening member to removably attach the second housing portion to the first housing portion.

In some embodiments, the coil spring may be structurally configured to encircle the fastening member that engages the first attachment portion and the second attachment portion.

In some embodiments, the coil spring may be positioned either between the first attachment portion and the second attachment portion or between the second attachment portion and a head portion of the fastening member.

In some embodiments, a cable tap may be structurally configured to maintain an electrical ground between loosely coupled housing portions to prevent or inhibit radio frequency interference. In some embodiments, the cable tap may include a first housing portion structurally configured to connect to an input communication cable and a second housing portion structurally configured to connect to an output communication cable, a signal processing portion structurally configured to receive and process a signal from the input communication cable and route a processed signal to the output communication cable.

In some embodiments, the cable tap may include a biasing portion structurally configured to maintain an electrically conductive connection between the first housing portion and the second housing portion when the first housing portion is loosely coupled with the second housing portion and the first and second mounting portions are not in contact and the signal processing portion is receiving the signal from the input communication cable so as to ground the first housing portion to the second housing portion and provide enhanced RF shielding.

In some embodiments, the first housing portion may include a first mounting portion and a first attachment portion. In some embodiments, the second housing portion may include a second mounting portion and a second attachment portion. In some embodiments, the second mounting portion may be structurally configured to contact the first mounting portion when the second housing portion is tightly coupled to the first housing portion.

In some embodiments, the first attachment portion and the second attachment portion may be structurally configured to engage a fastening member to attach the second housing portion to the first housing portion.

In some embodiments, the first housing portion and the second housing portion may be structurally configured to enclose the signal processing portion.

In some embodiments, the biasing portion may include a coil spring structurally configured to encircle the fastening member when the fastening member engages the first attachment portion and the second attachment portion.

In some embodiments, the biasing portion may be positioned between the first attachment portion and the second attachment portion.

In some embodiments, the fastening member may include a head portion and wherein the biasing portion is positioned between the second attachment portion and the head portion.

In some embodiments, the cable tap may include a radio frequency shielding portion structurally configured to inhibit radio frequency interference, wherein the biasing portion is positioned outward of the radio frequency shielding portion.

In some embodiments, the cable tap may include a sealing portion structurally configured to form a water-resistant seal between the first housing portion and the second housing portion, wherein the biasing portion is positioned outward of the sealing portion.

In some embodiments, a cable tap may be structurally configured to maintain an electrical ground between loosely coupled housing portions to prevent or inhibit radio frequency. In some embodiments, the cable tap may include a first housing portion structurally configured to connect to an input communication cable, a second housing portion structurally configured to connect an output communication cable, and a signal processing portion structurally configured to receive and process a signal from the input communication cable and route a processed signal to the output communication cable.

In some embodiments, the first housing portion may include a first mounting portion. In some embodiments, the second housing portion may include a second mounting portion structurally configured to contact the first mounting portion when the second housing portion is tightly coupled to the first housing portion.

In some embodiments, the cable tap may include a biasing portion structurally configured to maintain an electrically conductive connection between the first housing portion and the second housing portion when the first housing portion is loosely coupled with the second housing portion and first mounting portion and the second mounting portion are not in contact and the signal processing portion is receiving the signal from the input communication cable so as to ground the first housing portion to the second housing portion and provide enhanced RF shielding.

In some embodiments, the cable tap may include a radio frequency shielding portion structurally configured to inhibit radio frequency interference. In some embodiments, the biasing portion may be positioned outward of the radio frequency shielding portion.

In some embodiments, the cable tap may include a sealing portion structurally configured to form a water-resistant seal between the first housing portion and the second housing portion. In some embodiments, the biasing portion may be positioned outward of the sealing portion.

In some embodiments, the biasing portion may include a coil spring.

In some embodiments, the first housing portion and the second housing portion may be structurally configured to enclose the signal processing portion.

In some embodiments, the first housing portion may include a first attachment portion and the second housing portion includes a second attachment portion. In some embodiments, the first attachment portion and the second attachment portion may be structurally configured to engage a fastening member to removably attach the second housing portion to the first housing portion.

In some embodiments, the biasing portion may include a coil spring structurally configured to encircle the fastening member when the fastening member engages the first attachment portion and the second attachment portion.

In some embodiments, the fastening member may include a head portion and the biasing portion may be positioned between the second attachment portion and the head portion.

In some embodiments, the biasing portion may be positioned between the first attachment portion and the second attachment portion.

Various aspects of the system, as well as other embodiments, objects, features and advantages of this disclosure, will be apparent from the following detailed description of illustrative embodiments thereof, which is to be read in conjunction with the accompanying drawings.

### BRIEF DESCRIPTION OF THE DRAWINGS

The accompanying drawings, which are incorporated in and constitute a part of this specification, illustrate embodiments of the present teachings and together with the description, serve to explain the principles of the present teachings.

FIG. 1 is a schematic representation of an example cable tapping arrangement. FIG. 2 is a perspective view of an example cable tapping arrangement.

FIG. 3 is a top view of the cable tapping arrangement of FIG. 2 with a first housing portion separated from a second housing portion.

FIG. 4 is a partial sectioned side view of the cable tapping arrangement of FIG. 2.

FIG. 5 is an enlarged view of a sectioned corner of the cable tapping arrangement of FIG. 4 in a secure, or tightened, condition.

FIG. 6 is an enlarged view of a sectioned corner of the cable tapping arrangement of FIG. 4 in a loose condition.

FIG. 7 is a perspective view of an example biasing member installed on the second housing portion.

FIG. 8 is a perspective view cable tapping arrangement of FIG. 2 in the loose condition.

### DETAILED DESCRIPTION

Reference will now be made in detail to embodiments and methods of the present disclosure, which constitute the best modes of practicing the present disclosure presently known to the inventors. The figures are not necessarily to scale. It is to be understood, however, that the disclosed embodiments are merely exemplary of the present disclosure that may be embodied in various and alternative forms. Therefore, specific details disclosed herein are not to be interpreted as limiting, but merely as a representative basis for any aspect of the present disclosure and/or as a representative basis for teaching one skilled in the art to variously employ the present disclosure.

It is also to be understood that this present disclosure is not limited to the specific embodiments and methods described below, as specific components and/or conditions may, of course, vary. Furthermore, the terminology used herein is used only for the purpose of describing particular embodiments of the present disclosure and is not intended to be limiting in any way.

It must also be noted that, as used in the specification and the appended claims, the singular form “a,” “an,” and “the” comprise plural referents unless the context clearly indicates otherwise. For example, reference to a component in the singular is intended to comprise a plurality of components.

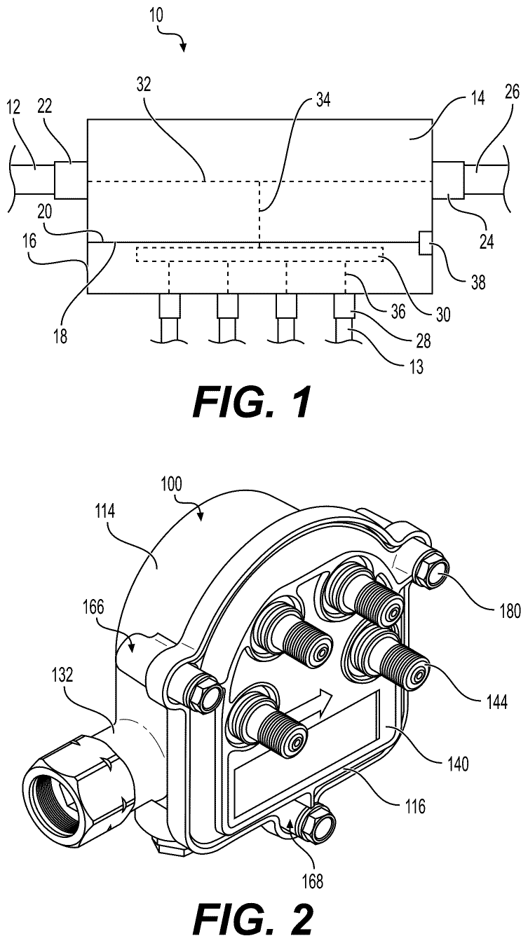

FIG. 1 shows an example cable tapping arrangement or cable tap 10 in accordance with aspects of the disclosure. The cable tapping arrangement 10 may be structurally configured to distribute radio frequency (RF) signals in a communication network (e.g., cable television network). In particular, the cable tapping arrangement 10 may be structurally configured to electrically or communicatively couple (e.g., allow for the transmission of a part of the signal of) a first inlet communication cable 12 (i.e., a trunk line or a feeder cable) to one or more second communication cables 13 (e.g., a drop line) structurally configured to carry the RF signal from the cable tapping arrangement 10 to an end-use device. The cable tapping arrangement 10 may be configured in a variety of ways.

In the illustrated example, the cable tapping arrangement 10 may include a first housing portion 14 and a second housing portion 16 structurally configured to be removably coupled to the first housing portion 14. The second housing portion 16 may be removably coupled to the first housing portion 14 in a variety of ways, such as, for example, by one or more fastening members (e.g., bolt, screw, latch, clasp, clamp, catch, snap connection, etc.). In some implementations, the first housing portion 14 may include a first mounting portion 18 (e.g., a first mating surface) structurally configured to engage a second mounting portion 20 (e.g., a second mating surface) of the second housing portion 16 when the second housing portion 16 is securely attached to the first housing portion 14 (i.e., the cable tapping arrangement is in a secure, or tightened, condition).

In some implementations, the first housing portion 14 may include first cable connecting portion 22 (e.g., a first female threaded port) structurally configured to operatively connect to the first inlet communication cable 12 and a second cable connecting portion 24 (e.g., a second female threaded port) structurally configured to operatively connect to a first outlet communication cable 26.

In some implementations, the second housing portion 16 may include one or more cable tap connecting portions 28. Each of the cable tap connecting portions 28 may be structurally configured to connect to a corresponding second communication cable 13. In some implementations, the second housing portion 16 may include a signal processing portion 30 (e.g., a circuit board) structurally configured to manipulate the RF signals from the first inlet communication cable 12 for distribution to the cable tap connecting portions 28.

As shown in FIG. 1, in some implementations, the cable tapping arrangement 10 may be structurally configured to electrically couple the first inlet communication cable 12 to the first outlet communication cable 26, as represented by dashed line 32. Further, the cable tapping arrangement 10 may be structurally configured to electrically couple the first inlet communication cable 12 to the signal processing portion 30, as represented by dashed line 34. Further, the cable tapping arrangement 10 may be structurally configured to electrically couple the signal processing portion 30 to the cable tap connecting portions 28, as represented by dashed lines 36.

In some implementations, the first housing portion 14 and the second housing portion 16 may be structurally configured to provide shielding to minimize RF interference. For example, in some implementations, the first housing portion 14 and the second housing portion 16 may be made from common metal RF shielding materials (e.g., copper, aluminum, nickel, etc.). Enclosing the signal processing portion 30 and associated connectors and components inside the first housing portion 14 and the second housing portion 16 considerably reduces RF interference. Furthermore, in some implementations, the first housing portion 14 and the second housing portion 16 may include one or more RF shielding members (e.g., RF gaskets) (not shown) positioned between the first mounting portion 18 and the second mounting portion 20.

In some implementations, the cable tapping arrangement 10 may include a biasing member 38. The biasing member 38 may be structurally configured to maintain a conductive connection between the first housing portion 14 and the second housing portion 16 when the first mounting portion 18 and the second mounting portion 20 are separated (i.e., break contact with each other) while the signal processing portion 30 is still receiving a portion of the RF signal from the first inlet communication cable 12.

For example, in some implementations, if the fastening members (not shown) attaching the second housing portion 16 to the first housing portion 14 are not properly tightened, the first mounting portion 18 and the second mounting portion 20 may not be in contact (i.e., the cable tapping arrangement 10 is in a loose condition). As a result, the shielding provided by the first housing portion 14 and the second housing (and any RF shielding members) may be compromised. The biasing member 38, however, may maintain contact between the first housing portion 14 and the second housing portion 16 to create an RF interference ground to the second housing portion 16.

The biasing member 38 may be structurally configured in a variety of ways, such as, for example, different shapes (e.g., strip, coil, bar, projection, cone, etc.), different sizes, different locations associated with the cable tapping arrangement 10 (e.g., internal to the cable tapping arrangement, external to the cable tapping arrangement, associate with a fastening member, etc.), different orientations, different materials (e.g., any suitable conductive metal), etc. Any configuration capable of maintaining contact between the first housing portion 14 and the second housing portion 16 when the cable tapping arrangement is in the loose condition to create an RF interference ground to the second housing portion 16 may be used.

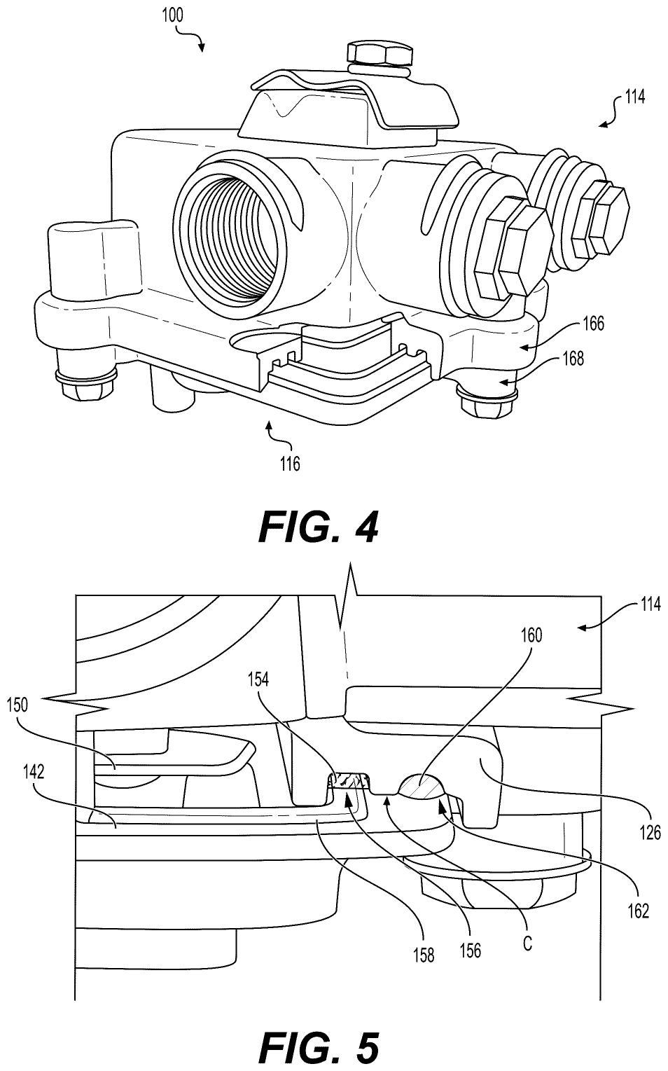

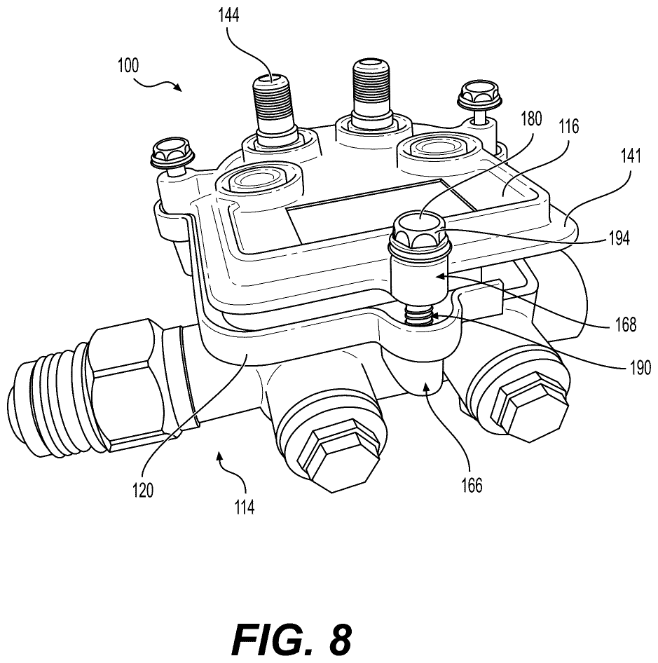

FIGS. 2-8 show an example cable tapping arrangement 100 in accordance with aspects of the disclosure. The cable tapping arrangement 100 may be structurally configured to distribute radio frequency (RF) signals in a communication network (e.g., cable television network). In particular, the cable tapping arrangement 100 may be structurally configured to electrically or communicatively couple (e.g., allow for the transmission of a part of the signal of) the first inlet communication cable 12 to one or more second communication cables 13 (FIG. 1). The cable tapping arrangement 100 may be configured in a variety of ways.

In some implementations, the cable tapping arrangement 100 may include a first housing portion 114 and a second housing portion 116 structurally configured to be removably coupled to the first housing portion 114. The first housing portion 114 may be configured in a variety of ways. In some implementations, the first housing portion 114 may include one or more walls 117 defining a first interior surface 118, a first exterior surface 120, and an interior space 122. In some implementations, the one or more walls 117 may include an edge portion 124 that defines a first mounting portion 126 and an opening 128 to the interior space 122.

In some implementations, the first housing portion 114 may include a first cable connecting portion 132 (e.g., a first female port) structurally configured to operatively connect to the first inlet communication cable 12 (FIG. 1) and a second cable connecting portion 134 (e.g., a second female port) structurally configured to operatively connect to the first outlet communication cable 26 (FIG. 1).

The second housing portion 116 may be configured in a variety of ways. In some implementations, the second housing portion 116 may include a second interior surface 138, a second exterior surface 140 opposite the second interior surface 138, and a lateral surface or edge 141 extending between the second interior surface 138 and the second exterior surface 140. In some implementations, the second interior surface 138 may include a second mounting portion 142 extending around, or adjacent to, a periphery of the second housing portion 116.

In some implementations, the second exterior surface 140 may include one or more cable tap connecting portions 144. Each of the one or more cable tap connecting portions 144 may be structurally configured to connect to a corresponding one or more second communication cables 13 (e.g., a drop line) (FIG. 1) that are structurally configured to carry the RF signal from the cable tapping arrangement 100 to an end-use device. The cable tap connecting portion 144 may be configured in a variety of ways, such as, for example, a F-Type Female connector.

The cable tapping arrangement 100 may be structurally configured to electrically couple the first inlet communication cable 12 to the first outlet communication cable 26. Further, the cable tapping arrangement 100 may be structurally configured to electrically couple the first inlet communication cable 12 to the one or more cable tap connecting portions 144 such that a part of the RF signal conveyed by the first inlet communication cable 12 may be routed to the one or more cable tap connecting portions 144. In some implementations, cable tapping arrangement 10 may include various connections and components (not shown) to facilitate conveying a part of the RF signal from the first inlet communication cable 12 to the one or more cable tap connecting portions 144. In some implementations, the connections and components may be conventional and known in the art.

For example, in some implementations, the cable tapping arrangement 100 may include a signal processing portion 150 (e.g., a circuit board) structurally configured to receive and process or manipulate a RF signal from the first inlet communication cable 102 and route the processed signal(s) to the one or more cable tap connecting portions 144. In some implementations, signal processing portion 150 may be configured in a conventional manner known in the art.

In some implementations, the signal processing portion 150 may be structurally configured to mount to the second housing portion 116. For example, in some implementations, the signal processing portion 150 may be structurally configured to mount to the second interior surface 138.

The second housing portion 116 may be removably coupled to the first housing portion 114 in a variety of ways. For example, in some implementations, the second mounting portion 142 may be structurally configured to engage or contact the first mounting portion 126 when the second housing portion 116 is coupled to the first housing portion 114. In some implementations, when the second housing portion 116 is coupled to the first housing portion 114, the second housing portion 116 may be structurally configured to cover the opening 128 to the interior space 122. In some implementations, when the second housing portion 116 covers the opening 128 to the interior space 122, the first housing portion 114 and the second housing portion 116 are structurally configured to enclose the signal processing portion 150 and the various connections and components (not shown) that facilitate conveying a part of the RF signal from the first inlet communication cable 12 to the one or more cable tap connecting portions 144.

In some implementations, the first housing portion 114 and the second housing portion 116 may be structurally configured to provide shielding to minimize RF interference. For example, in some implementations, the first housing portion 114 and the second housing portion 116 may be made from common metal RF shielding materials (e.g., copper, aluminum, nickel, etc.). Enclosing the signal processing portion 150 and associated connectors and components inside the first housing portion 114 and the second housing portion 116 considerably reduces RF interference.

In some implementations, the cable tapping arrangement 100 may include a radio frequency shielding portion 152 structurally configured to prevent or inhibit unwanted radio frequency egress or ingress (e.g., radio frequency interference) associated with the cable tapping arrangement 100. In some implementations, the radio frequency shielding portion 152 may be structurally configured to be supported by the first mounting portion 126 and structurally configured to engage the second mounting portion 142 to form a radio frequency barrier therebetween. In other implementations, the radio frequency shielding portion 152 may be structurally configured to be supported by the second mounting portion 142 and structurally configured to engage the first mounting portion 126 to form a radio frequency barrier therebetween.

In some implementations, the radio frequency shielding portion 152 may include a radio frequency gasketing portion 154 structurally configured to be received in a first groove or recess 156 in the first mounting portion 126. The radio frequency gasket portion 154 may be configured in a variety of ways. In some implementations, the radio frequency gasket portion 154 may be a metal mesh material. In some implementations, the second mounting portion 142 may include a corresponding ridge or projection 158 structurally configured to engage the radio frequency gasket portion 154 when the second housing portion 116 is attached to the first housing portion 114.

In some implementations, the cable tapping arrangement 100 may include a sealing portion 160 structurally configured to seal the interior space from environmental conditions (e.g., prevent the ingress of water, dirt, etc.). In some implementations, the sealing portion 160 may be structurally configured to provide a water-resistant or waterproof seal. The sealing portion 160 may be configured in a variety of ways. In some implementations, the sealing portion 160 may be structurally configured to be supported by the first mounting portion 126 and structurally configured to engage the second mounting portion 142 to form a seal therebetween. In other implementations, the sealing portion 160 may be structurally configured to be supported by the second mounting portion 142 and structurally configured to engage the first mounting portion 126 to form a seal therebetween.

In some implementations, the sealing portion 160 may be structurally configured to be received in a second groove or recess 162 in the first mounting portion 126. In some implementations, the sealing portion 160 may be a rubber material or other suitable elastic material. In some implementations, the sealing portion 160 may be positioned outward of the radio frequency shielding portion 152.

The second housing portion 116 may be secured, or tightened, to the first housing portion 114 in a variety of ways. In some implementations, the first housing portion 114 may include a first attachment portion 166 and the second housing portion 116 may include a second attachment portion 168. The first attachment portion 166 and the second attachment portion 168 may be structurally configured to cooperate with each other to secure the second housing portion 116 to the first housing portion 114. The first attachment portion 166 and the second attachment portion 168 may be configured in a variety of ways. In some implementations, the first attachment portion 166 may include one or more first fastening members engaging portions 170 and the second attachment portion 168 may include one or more second fastening member engaging portions 172.

In some implementations, the first fastening member engaging portion 170 and the second fastening member engaging portions 172 are configured as mounting bosses extending from the first exterior surface 120 and the lateral surface 141, respectively. In some implementations, each first fastening member engaging portion 170 may include a first fastening member receiving opening 174 and each second fastening member engaging portion 172 may include a second fastening member receiving opening 176.

When the second housing portion 116 is properly positioned to engage the first housing portion, the first fastening member receiving opening 174 and the second fastening member receiving opening 176 may align such that a fastening member 180 may be received therethrough. Thus, the first fastening member engaging portion 170 and the second fastening member engaging portions 172 may engage with one or more of the fastening members 180 to secure the second housing portion 116 to the first housing portion 114.

As shown in FIG. 5, in some embodiments, in a secure, or tightened, condition, the fastening members 180 may be sufficiently tightened such that the first mounting portion 126 and the second mounting portion 142 may contact or engage each other, as illustrated by arrow C. In some embodiments, in the secure, or tightened, condition, the radio frequency shielding portion 152 and the sealing portion 160 may be engaged by both the first mounting portion 126 and the second mounting portion 142 to form a radio frequency barrier and seal against environmental conditions, respectively.

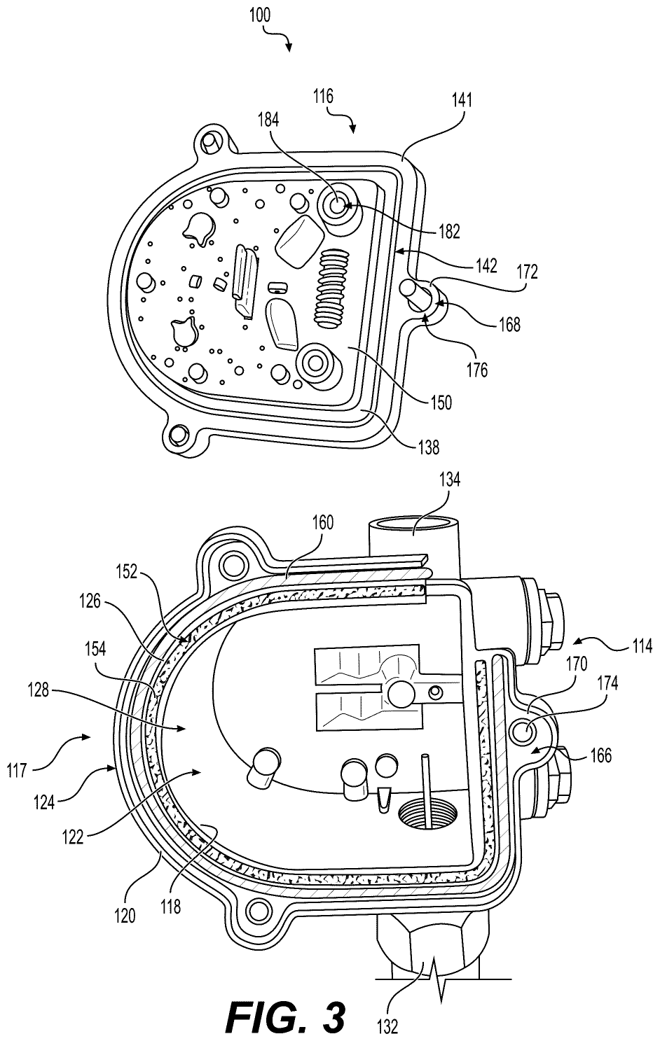

In some implementations, when the second housing portion 116 is attached to the first housing portion 114, the signal processing portion 150 may be structurally configured to operatively connect to the first inlet communication cable 12. For example, in some implementations, the signal processing portion 150 may include a coupling portion 182 (FIGS. 3 and 7) structurally configured to operatively connect to a connector (not shown) associated with the first inlet communication cable 12 to operatively connect (e.g., establish an electrical connection) with first inlet communication cable 12. In some implementations, the coupling portion 182 may include a female port 184 structurally configured to receive a male projection or pin (not shown) associated with the first inlet communication cable 12.

In some implementations, the coupling portion 182 may operatively connect to the first inlet communication cable 12 prior to the first mounting portion 126 and the second mounting portion 142 coming into contact. For example, in some implementations, the male projection or pin (not shown) associated with the first inlet communication cable 12 may be received in the female port 184 before the first mounting portion 126 and the second mounting portion 142 coming into contact.

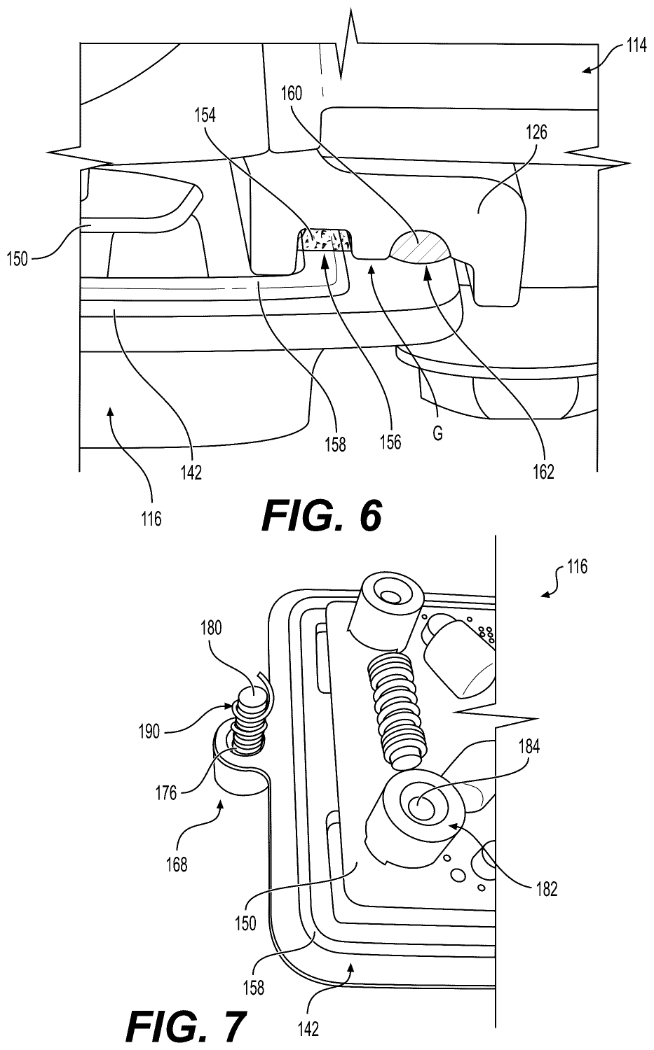

FIG. 6 illustrates the cable tapping arrangement 100 in a loose condition in which the first mounting portion 126 and the second mounting portion 142 are not in contact or there is play therebetween, as shown by a gap G between the mounting portions 126, 142, but are close enough that the coupling portion 182 may be operatively connect to the first inlet communication cable 12. This may occur, for example, if the fastening members are not sufficiently tightened such that the second mounting portion 142 separates from the first mounting portion 126 or corrosion occurs at the mounting portions 114, 116 preventing the mounting portions 114, 116 from properly engaging. As a result, the radio frequency interference protection of enclosing the signal processing portion 150 and associated components and connections within the first and section housing portions and barrier provided by the radio frequency shielding portion 152 may be compromised.

In some implementations, the cable tapping arrangement 100 may include a biasing portion 190. The biasing portion 190 may be structurally configured to maintain a conductive connection between the first housing portion 114 and the second housing portion 116 in the loose condition. For example, in some implementations, the biasing portion 190, may be structurally configured to maintain contact between the first housing portion 114 and the second housing portion 116 in the loose condition to create an RF interference ground to the second housing portion 116.

The biasing portion 190 may be structurally configured in a variety of ways, such as, for example, different shapes (e.g., strip, coil, bar, projection, cone, etc.), different sizes, different locations associated with the cable tapping arrangement 100 (e.g., internal to the cable tapping arrangement, external to the cable tapping arrangement, associate with a fastening members, etc.), different orientations, different materials (e.g., any suitable conductive metal), etc. Any configuration capable of maintaining a conductive connection between the first housing portion 114 and the second housing portion 116 in the loose condition to create an RF interference ground to the second housing portion 116 may be used.

In some implementations, the biasing portion 190 may be positioned outward of the radio frequency shielding portion 152 and the sealing portion 160. In other implementations, however, the biasing portion 190 may be positioned inward or between the radio frequency shielding portion 152 and the sealing portion 160.

In some implementations, the biasing portion 190 may be associated with the first mounting portion 126 and/or the second mounting portion 142. In some implementations, the biasing portion 190 may be structurally configured to encircle the fastening member 180 engages the first attachment portion 166 and the second attachment portion 168.

In some implementations, the biasing portion 190 may include an elastic biasing member 192 structurally configured to maintain the conductive connection between the first housing portion 114 and the second housing portion 116 over a range of movement of the second housing portion 116 relative to the first housing portion 114. In some implementations, the biasing portion 190 may be coil spring received around the fastening member 180 and positioned between first attachment portion 166 and the second attachment portion 168.

In some embodiments, the fastening member 180 may have a head portion 194 (e.g., a head of a bolt) and biasing portion 190 may be coil spring received around the fastening member 180 and positioned between the second attachment portion 168 and the head portion 194. In some embodiments, the biasing portion may bias the second housing portion 116 toward the first housing portion 114.

While at least one example, non-limiting embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing the exemplary embodiment or exemplary embodiments. It should be understood that various changes can be made in the function and arrangement of elements without departing from the scope of the disclosure as set forth in the appended claims and the legal equivalents thereof.

What is claimed is:

1. A cable tap structurally configured to maintain an electrical ground between loosely coupled housing portions to prevent or inhibit radio frequency interference, comprising:
a first housing portion structurally configured to connect to an input communication cable, wherein the first housing portion includes a first mounting portion;
a second housing portion structurally configured to be coupled with the first housing portion and to connect to an output communication cable, wherein the second housing portion includes a second mounting portion structurally configured to contact the first mounting portion when the second housing portion is attached to the first housing portion;
a biasing portion structurally configured to create an electrically conductive connection between the first housing portion and the second housing portion;
a radio frequency shielding portion supported on the first mounting portion and structurally configured to engage the second mounting portion to form a radio frequency barrier therebetween;
a sealing portion supported on the first mounting portion and structurally configured to engage the second mounting portion to form a water-resistant seal therebetween;
wherein the second housing portion includes a signal processing portion structurally configured to receive and process a signal from the input communication cable and route a processed signal to the output communication cable;
wherein the first housing portion and the second housing portion are structurally configured to enclose the signal processing portion when the second housing portion is attached to the first housing portion;
wherein the radio frequency shielding portion is positioned inward of the sealing portion;
wherein the biasing portion is positioned outward of the radio frequency shielding portion and the sealing portion; and
wherein the biasing portion is structurally configured to maintain the electrically conductive connection between the first housing portion and the second housing portion when the first housing portion is loosely coupled with the second housing portion and first mounting portion and the second mounting portion are not in contact and the signal processing portion is receiving the signal from the input communication cable so as to ground the first housing portion to the second housing portion and provide enhanced RF shielding.

2. The cable tap according to claim 1, wherein the biasing portion comprises a coil spring.

3. The cable tap according to claim 2, wherein the first housing portion includes a first attachment portion, and the second housing portion includes a second attachment portion, and wherein the first attachment portion and the second attachment portion are structurally configured to engage a fastening member to removably attach the second housing portion to the first housing portion.

4. The cable tap according to claim 3, wherein the coil spring is structurally configured to encircle the fastening member that engages the first attachment portion and the second attachment portion.

5. The cable tap according to claim 3, wherein the coil spring is positioned either between the first attachment portion and the second attachment portion or between the second attachment portion and a head portion of the fastening member.

6. A cable tap structurally configured to maintain an electrical ground between loosely coupled housing portions to prevent or inhibit radio frequency interference, comprising:
a first housing portion structurally configured to connect to an input communication cable, wherein the first housing portion includes a first mounting portion and a first attachment portion;
a second housing portion structurally configured to connect to an output communication cable, wherein the second housing portion includes a second mounting portion and a second attachment portion, wherein the second mounting portion is structurally configured to contact the first mounting portion when the second housing portion is tightly coupled to the first housing portion, wherein the first attachment portion and the second attachment portion are structurally configured to engage a fastening member to attach the second housing portion to the first housing portion;
a signal processing portion structurally configured to receive and process a signal from the input communication cable and route a processed signal to the output communication cable, wherein the first housing portion and the second housing portion are structurally configured to enclose the signal processing portion; and
a biasing portion structurally configured to maintain an electrically conductive connection between the first housing portion and the second housing portion when the first housing portion is loosely coupled with the second housing portion and first mounting portion and the second mounting portion are not in contact and the signal processing portion is receiving the signal from the input communication cable so as to ground the first housing portion to the second housing portion and provide enhanced RF shielding.

7. The cable tap according to claim 6, wherein the biasing portion comprises a coil spring structurally configured to encircle the fastening member when the fastening member engages the first attachment portion and the second attachment portion.

8. The cable tap according to claim 6, wherein the biasing portion is positioned between the first attachment portion and the second attachment portion.

9. The cable tap according to claim 6, wherein the fastening member includes a head portion and wherein the biasing portion is positioned between the second attachment portion and the head portion.

10. The cable tap according to claim 6, further comprising a radio frequency shielding portion structurally configured to inhibit radio frequency interference, wherein the biasing portion is positioned outward of the radio frequency shielding portion.

11. The cable tap according to claim 6, further comprising a sealing portion structurally configured to form a water-resistant seal between the first housing portion and the second housing portion, wherein the biasing portion is positioned outward of the sealing portion.

12. A cable tap structurally configured to maintain an electrical ground between loosely coupled housing portions to prevent or inhibit radio frequency interference, comprising:
a first housing portion structurally configured to connect to an input communication cable, wherein the first housing portion includes a first mounting portion;
a second housing portion structurally configured to connect an output communication cable, wherein the second housing portion includes a second mounting portion structurally configured to contact the first mounting portion when the second housing portion is tightly coupled to the first housing portion;
a signal processing portion structurally configured to receive and process a signal from the input communication cable and route a processed signal to the output communication cable; and
a biasing portion structurally configured to maintain an electrically conductive connection between the first housing portion and the second housing portion when the first housing portion is loosely coupled with the second housing portion and first mounting portion and the second mounting portion are not in contact and the signal processing portion is receiving the signal from the input communication cable so as to ground the first housing portion to the second housing portion and provide enhanced RF shielding.

13. The cable tap according to claim 12, further comprising a radio frequency shielding portion structurally configured to inhibit radio frequency interference, wherein the biasing portion is positioned outward of the radio frequency shielding portion.

14. The cable tap according to claim 12, further comprising a sealing portion structurally configured to form a water-resistant seal between the first housing portion and the second housing portion, wherein the biasing portion is positioned outward of the sealing portion.

15. The cable tap according to claim 12, wherein the biasing portion comprises a coil spring.

16. The cable tap according to claim 12, wherein the first housing portion and the second housing portion are structurally configured to enclose the signal processing portion.

17. The cable tap according to claim 12, wherein the first housing portion includes a first attachment portion, and the second housing portion includes a second attachment portion, and wherein the first attachment portion and the second attachment portion are structurally configured to engage a fastening member to removably attach the second housing portion to the first housing portion.

18. The cable tap according to claim 17, wherein the biasing portion comprises a coil spring structurally configured to encircle the fastening member when the fastening member engages the first attachment portion and the second attachment portion.

19. The cable tap according to claim 18, wherein the fastening member includes a head portion and wherein the biasing portion is positioned between the second attachment portion and the head portion.

20. The cable tap according to claim 17, wherein the biasing portion is positioned between the first attachment portion and the second attachment portion.
